(19) United States
(12) Patent Application Publication
(10) Pub. No.: US 2026/0322283 A1
(43) Pub. Date: Oct. 15, 2026

(54) Methods and Circuits for Transferring a Signal Across an Isolation Barrier

(71) Applicant: Queen's University at Kingston, Kingston (CA)

(72) Inventors: Yan-Fei Liu, Kingston (CA); Bo Sheng, Kingston (CA); Xiang Yu, Kingston (CA); Yang Chen, Shenzhen (CN); Binghui He, Kingston (CA)

(21) Appl. No.: 18/998,731

(22) PCT Filed: Jul. 26, 2023
(86) PCT No.: PCT/CA2023/051003

§ 371 Date: Jan. 27, 2025

Related U.S. Application Data
(60) Provisional application No. 63/392,715, filed on Jul. 27, 2022.

(51) Int. Cl. H02M 3/335; H02M 1/00; H02M 3/00; H03M 7/00

(52) U.S. Cl. CPC H02M 3/33573; H02M 1/0003; H02M 3/01; H02M 3/33592; H03M 7/00

(57) ABSTRACT

Methods for transferring a signal across an isolation barrier include encoding the signal according to at least first and second parameters at a second side of the isolation barrier and using one or more isolating device to transfer the signal to a first side of the isolation barrier, where it is decoded to recover the at least first and second parameters. Encoding the signal may include encoding a first feature of the signal according to the first parameter and encoding a second feature of the signal according to the second parameter. Software products that implement the methods may be executed in processors on primary and secondary sides of an isolation barrier. An isolated power converter may include primary and secondary side controllers that execute the software products, wherein the parameters recovered on the primary side may be used to control the converter, such as for output voltage regulation.

### RELATED APPLICATION

This application claims the benefit of the filing date of Application No. 63/392,715, filed on Jul. 27, 2022, the contents of which are incorporated herein by reference in their entirety.

### FIELD

This invention relates to isolated power converters. More specifically, the invention relates to methods and circuits for accurate sensing of the output voltage of isolated power converters and transferring the sensed output voltage across the converter isolation barrier without any accuracy loss. One optocoupler may be used to achieve accurate output voltage regulation with fast response time. Additional information can also be transferred from the secondary side to primary side accurately.

### BACKGROUND

Isolated power converters are used extensively in applications such as battery chargers, data center power supplies, chargers for devices such as cell phones, tablets, and laptop computers, etc. An example of an isolated DC-DC converter according to the prior art is shown in FIG. 1. Referring to FIG. 1, is an isolated converter the primary (input) side is isolated from the secondary (output) side, which may be achieved by a transformer Tx. Regulation of the output voltage Vo is achieved by a digital controller such as a micro-controller unit MCU2 on the primary side. To achieve voltage regulation, a feedback signal such as an error voltage based on the output voltage Vo is used as an input to the controller MCU2. Because of the need to maintain electrical isolation between the input side and the output side, an optocoupler OP1 is typically used to transfer the error voltage Verror1 on the secondary side to an error voltage Verror2 on the primary side, as input to the controller MCU2. However, a limitation of current approaches is that the error voltage Verror2 is not directly proportional to Vo, and as a result precise output voltage information cannot be obtained at the primary side.

### SUMMARY

According to one aspect of the invention there is provided a method for transferring a signal across an isolation barrier, comprising: encoding the signal according to at least first and second parameters at a second side of the isolation barrier; using one or more isolating device to transfer the signal to a first side of the isolation barrier; decoding the signal to recover the at least first and second parameters on the first side of the isolation barrier; wherein encoding the signal comprises encoding a first feature of the signal according to the first parameter and encoding a second feature of the signal according to the second parameter.

In one embodiment the method may comprise organizing the signal in an information transfer protocol, comprising: a starter frame having a first selected number of pulses; and an information frame having a second selected number of pulses comprising the first feature and the second feature; wherein encoding comprises encoding the first feature of the second selected number of pulses according to analog information about the first parameter and encoding the second feature of the second selected number of pulses according to digital information about the second parameter.

In one embodiment the first feature of at least one of the first and second selected number of pulses is a pulse width and the second feature of the second selected number of pulses is a pulse period.

In one embodiment encoding may comprise encoding analog information about the first parameter in at least one of the first and second selected number of pulses by adjusting the pulse width according to the analog information.

In one embodiment encoding may comprise encoding digital information about the second parameter in the second selected number of pulses by selecting a first pulse period to be digital 1 (Ts1) and selecting a second pulse period (Ts0) to be digital 0.

In one embodiment the method may comprise encoding the signal with a supplemental frame having a selected number of pulses that encode information about one or more other parameters of the second side of the isolation barrier.

In one embodiment encoding may comprise encoding analog information about the one or more other parameters in the selected number of pulses by adjusting the pulse width according to the one or more other parameters.

In one embodiment the method may comprise encoding the signal with a check frame having a selected number of pulses that encode cyclic redundancy check (CRC) bits.

In one embodiment encoding may comprise encoding analog information about one or more other parameters in the selected number of pulses by adjusting the pulse width according to the one or more other parameters.

In one embodiment the method may comprise using a length of a pulse in the starter frame as a reference to calibrate a length of Ts1 and Ts0 at the first side of the isolation barrier.

In one embodiment the method may comprise using a digital value of the second parameter transferred from the second side of the isolation barrier to calibrate an actual value of the first parameter at the first side of the isolation barrier.

In one embodiment the method may comprise using a second controller at the second side of the isolation barrier to implement encoding the signal, and using a first controller at the first side of the isolation barrier to implement decoding the signal. In one embodiment the first controller uses information about the first parameter and/or information about the second parameter obtained from decoding the signal to control operation of a circuit on the first side of the isolation barrier.

In one embodiment the isolation barrier isolates first (primary) and second (secondary) sides of an isolated power converter.

In one embodiment the isolating device comprises a device selected from an optocoupler and a digital isolator.

In one embodiment the one or more isolating device comprises an optocoupler.

In one embodiment the first parameter may be an instantaneous output voltage of an isolated power converter and the second parameter may be average output voltage of the isolated power converter.

According to another aspect of the invention there is provided programmed media for use with at least a first controller and a second controller connected to respective first and second sides of one or more isolating device disposed across an isolation barrier, comprising: a code stored on non-transitory computer readable storage media compatible with processors of the at least first and second controllers, the code containing instructions to direct the processors to implement a strategy to transfer a signal across the isolation barrier, comprising: the second controller encoding a signal according to at least first and second parameters at the second side of the isolation barrier and outputting the encoded signal to the one or more isolation device; the first controller receiving the encoded signal from the one or more isolation device and decoding the signal to recover the at least first and second parameters on the first side of the isolation barrier; wherein encoding the signal comprises encoding a first feature of the signal according to the first parameter and encoding a second feature of the signal according to the second parameter.

In one embodiment of the programmed media the second controller organizes the signal in an information transfer protocol, comprising: a starter frame having a first selected number of pulses; and an information frame having a second selected number of pulses comprising the first feature and the second feature; wherein encoding comprises encoding the first feature of the second selected number of pulses according to analog information about the first parameter and encoding the second feature of the second selected number of pulses according to digital information about the second parameter.

In one embodiment of the programmed media the first feature of at least one of the first and second selected number of pulses is a pulse width and the second feature of the second selected number of pulses is a pulse period.

In one embodiment of the programmed media encoding comprises encoding analog information about the first parameter in at least one of the first and second selected number of pulses by adjusting the pulse width according to the analog information.

In one embodiment of the programmed media encoding comprises encoding digital information about the second parameter in the second selected number of pulses by selecting a first pulse period to be digital 1 (Ts1) and selecting a second pulse period (Ts0) to be digital 0.

In one embodiment of the programmed media encoding comprises encoding the signal with a supplemental frame having a selected number of pulses that encode information about one or more other parameters of the second side of the isolation barrier.

In one embodiment of the programmed media encoding comprises encoding analog information about the one or more other parameters in the selected number of pulses by adjusting the pulse width according to the one or more other parameters.

In one embodiment of the programmed media encoding comprising encoding the signal with a check frame having a selected number of pulses that encode cyclic redundancy check (CRC) bits.

In one embodiment of the programmed media encoding comprises encoding analog information about one or more other parameters in the selected number of pulses by adjusting the pulse width according to the one or more other parameters.

One embodiment of the programmed media comprises using a length of a pulse in the starter frame as a reference to calibrate a length of Ts1 and Ts0 at the first side of the isolation barrier.

One embodiment of the programmed media comprises using a digital value of the second parameter transferred from the second side of the isolation barrier to calibrate an actual value of the first parameter at the first side of the isolation barrier.

In one embodiment of the programmed media the first controller and the second controller are implemented in first (primary) and second (secondary) sides of an isolated power converter.

In one embodiment of the programmed media the first parameter is instantaneous output voltage of the isolated power converter and the second parameter is average output voltage of the isolated power converter.

In one embodiment of the programmed media the first controller uses information about the first parameter and/or information about the second parameter obtained from decoding the signal to control operation of a circuit on the first side of the isolation barrier.

According to another aspect of the invention there is provided an isolated power converter comprising: a primary side controller; a secondary side controller; and one or more isolating device that transfers a pulse signal across an isolation barrier; wherein the secondary side controller encodes information about at least one parameter of the isolated power converter by controlling at least one feature of the pulse signal according to levels of the at least one parameter.

In one embodiment the at least one feature is a period of the pulse signal; and the secondary side controller encodes the information using at least two different periods of the pulse signal.

In one embodiment the at least one feature is a pulse duration of the pulse signal; and the secondary side controller encodes the information using a variable pulse duration of the pulse signal.

In one embodiment a first feature is a period of the pulse signal; a second feature is a pulse duration of the pulse signal; and the secondary side controller encodes the information using at least two different periods and a variable pulse duration of the pulse signal.

In one embodiment the isolated power converter includes programmed media as described herein.

In various embodiments the isolated power converter may have a voltage regulation to about 0.5% or better of a normal output voltage.

### BRIEF DESCRIPTION OF THE DRAWINGS

For a better understanding of the invention, and to show more clearly how it may be carried into effect, embodiments will be described below, by way of example, with reference to the accompanying drawings, wherein:

FIG. 1 is a schematic diagram of an isolated inductor-inductor-capacitor (LLC) converter operating as DC-to-DC converter with a controller at the primary side, according to the prior art.

FIG. 2 is a schematic diagram of an isolated converter with controllers at the primary and secondary sides, wherein the output voltage and error of output voltage are transferred to the primary side using two opto-couplers, according to the prior art.

FIG. 3 is a schematic diagram of an isolated converter with controllers at the primary and secondary sides, wherein the output voltage is transferred to the primary side using one digital isolator, according to the prior art.

FIG. 4 is a waveform of a typical logic pulse signal.

FIG. 5 is waveform of three pulse signals with different Ton and Ts, according to one embodiment.

FIG. 6 is waveform of four pulse signals with different Ton and Ts1, Ts0, according to one embodiment.

FIG. 7 is a diagram showing how a Vsignal waveform is used at an IO pin of a primary side controller, according to one embodiment.

FIG. 8A shows a schematic diagram of a circuit that may be used to implement an embodiment.

FIG. 8B shows waveforms for transferring pulse signals from secondary side to primary side under ideal conditions, according to an embodiment.

FIG. 8C shows waveforms for transferring pulse signals from secondary side to primary side when the timing at secondary side and primary side is slightly different, according to one embodiment.

### DETAILED DESCRIPTION OF EMBODIMENTS

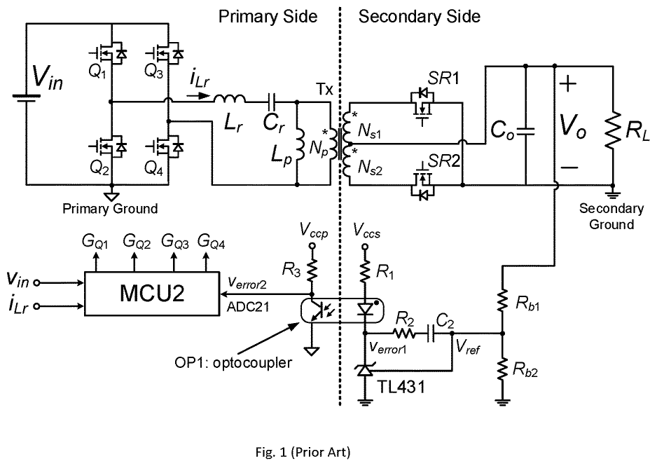

FIG. 1 shows an isolated DC to DC converter with full bridge inductor-inductor-capacitor (LLC) converter as the power stage, according to the prior art. It is noted that a transformer Tx is used to achieve isolation between the primary side (shown on the left side of the dotted line) and the secondary side (shown on the right side of the dotted line). Np refers to the transformer primary winding and Ns1, Ns2 refer to transformer secondary windings.

MCU2 in FIG. 1 refers to a microcontroller unit. It is a digital controller that is used to control the operation of the LLC converter by providing switching signals (G_{Q1}-G_{Q4}) to the power switches Q₁-Q₄ of the power converter primary side. In this circuit, output voltage Vo regulation is achieved by transferring the value of error voltage Verror1 from the secondary side across the isolation barrier to primary side as Verror2, for use by the digital controller MCU2.

In FIG. 1 MCU2 is placed at the primary side of the power supply. The output voltage Vo at the secondary side passes through a resistor divider circuit (Rb1, Rb2) connected to a voltage regulator TL431, which sets a reference voltage Vref and includes an OpAmp. The output of the TL431 (Verror1) changes and therefore, the current through the diode of the analog optocoupler OP1 changes. The output current of the analog optocoupler OP1 (i.e., the current through the bipolar junction transistor (BJT)) is proportional to its input current (i.e., the current through the diode), so that the error voltage at the primary side, Verror2, also changes. Verror2 is converted into digital value by an analog to digital converter (ADC) in MCU2 through pin ADC21. The MCU2 processes the error information and generates a control signal, such as switching frequency of the LLC converter, through four gate drive signals G_{Q1}-G_{Q4}. In some cases, the resonant current and input voltage are also sensed and used by MCU2.

It is noted that Verror2 contains the error information of the output voltage. In the case shown in FIG. 1, Verror2 depends on the compensation network (R2, C2), the reference voltage Vref of TL431, the Current Transfer Ratio (CTR) of the analog optocoupler OP1, and values of resistors R1, R3, Rb1, and Rb2, as shown in equation (1)

$$error 2 = f ( Vref , R 2 , C 2 , CTR , Rb 1 , Rb 2 ) \qquad ( 1 )$$

wherein f is typically a complex function.

However, according to the prior approach of FIG. 1, Verror2 is not directly proportional to Vo, as shown below:

$$Verror 2 \neq k Vo \qquad ( 2 )$$

In the above equation k is a constant, and it can be seen that the actual Vo value is not available from Verror2.

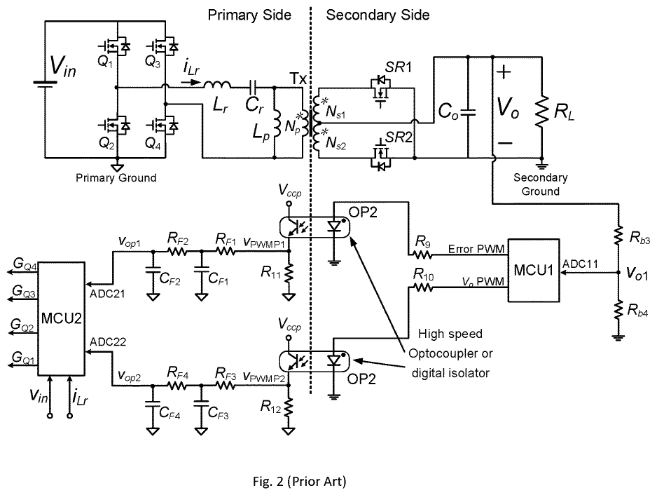

FIG. 2 is a schematic diagram of a circuit for transferring the output voltage and error of output voltage using two high speed optocouplers, or digital isolators, according to the prior art. One digital isolator transfers the output voltage signal and the other digital isolator transfers the error voltage signal.

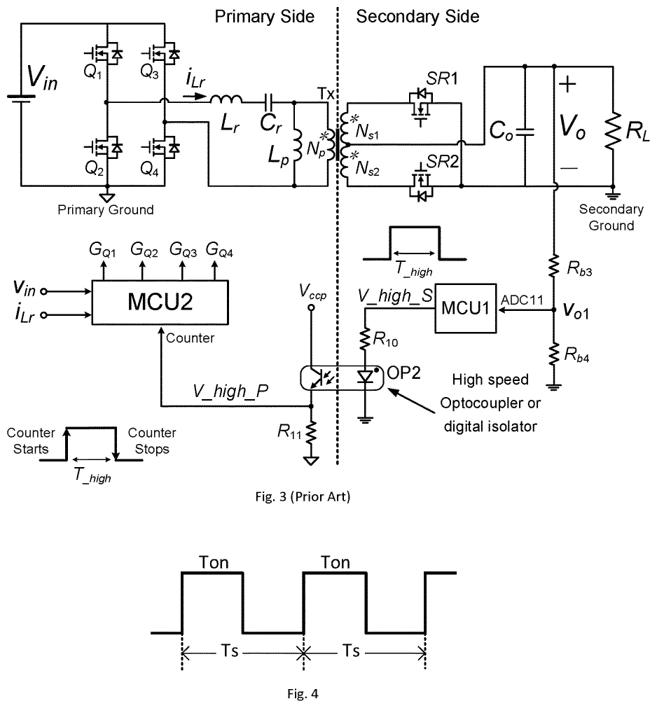

FIG. 3 is a schematic diagram of a circuit for transferring the output voltage directly using one digital isolator, according to the prior art. With this method, the output voltage value Vo is converted directly to a time interval when the pulse signal is logic high T_high.

In this specification the terms “analog optocoupler”, “digital optocoupler”, “high speed optocoupler” and “digital isolator” are used interchangeably. All refer to a device that can transfer digital signals (e.g., pulse signals) from one side of an isolation barrier to the other, such as shown in FIG. 2 and FIG. 3. All types of devices may be used in embodiments described herein. In this specification the symbol for an optocoupler is used in the figures to show the direction of information transfer. The information at the diode side is the input and the information at the transistor (e.g., BJT) side is the output. Digital isolators and high speed optocouplers can transfer signals at frequencies of, e.g., 50 kHz, or higher. The term “optocoupler” refers to a device that can transfer analog signals or low frequency pulse signals from one isolation side to another. An optocoupler can transfer signals at frequencies lower than around 10 kHz accurately. In FIG. 1, the low frequency signal is transferred from secondary side (diode side, or right side) to primary side (transistor side, or left side). Any of such devices may be referred to herein as an “isolating device”.

The circuit shown in FIG. 3 uses one digital isolator so that the T_high interval for signal V_high_S at secondary side is very close to the T_high interval for signal V_high_P at primary side. The prior approach of FIG. 3 has two limitations: (1) it will increase the cost of the power supply since digital isolator is more expensive than an analog optocoupler; and (2) due to delay time inherent to the digital isolator and the variation of clock frequency of MCU1 and MCU2, the actual T_high interval at V_high_P signal is not strictly proportional to Vo1 and therefore a small error will still be introduced. In addition, since the T_high time interval is directly proportional to the system clock of MCU1, when the system clock frequency of MCU1 changes at different temperatures or from component tolerances of different MCU units, the accuracy of the Vo sense method suffers. For example, if the system clock frequency of MCU1 changes by 5%, the value of T_high will change by 5%. Therefore, the measured output voltage will also be changed by 5%. When all the possible errors are included, the overall measurement error will be high enough to significantly degrade voltage regulator performance.

This problem may be partly addressed by using two optocouplers (or digital isolators) to transfer the Vo information from secondary side to primary side of an isolated power supply, shown in FIG. 2. However, an R and C filter is used to retrieve the DC value from the PWM signal, which will introduce some time delay.

Described herein are methods, circuits, and software products for implementing a coding strategy that may be used to transfer signals across an isolation barrier. Coding may include encoding a signal according to at least two parameters of interest at a second side of the isolation barrier, using an isolating device to transfer the signal to a first side of the isolation barrier, and decoding the signal to recover the at least two parameters on the first side of the isolation barrier. Encoding the signal may include encoding a first feature of the signal according to one of the parameters (i.e., “first parameter”) and encoding a second feature of the signal according to another parameter (i.e., “second parameter”). In some embodiments the first feature of the signal is a pulse width and the second feature of the signal is a pulse period. In some embodiments encoding includes encoding analog information about the first parameter by adjusting the pulse width according to the analog information, and encoding digital information about the second parameter by adjusting the pulse period. Typically it may not matter which of the two parameters is used as the first parameter and which is used as the second parameter. Rather, this is considered a design choice.

A coding strategy as described herein advantageously allows a signal encoded with information related to at least two parameters on interest to be transferred across an isolation barrier using only single isolating device. However, embodiments may be implemented using more than one isolating device. For example, a first parameter may be encoded in a feature of a first signal, and the first signal transferred across the isolation barrier using a first isolating device, and a second parameter may be encoded in a feature of a second signal, and second signal transferred across the isolation barrier using a second isolating device.

Although not limited thereto, embodiments may be configured to transfer signals across the isolation barrier of an isolated power converter. For example, a signal transferred across the isolation barrier may contain information about first and second parameters of interest such as, for example, the instantaneous output voltage value Vo and the steady state output voltage value Vo_ss, to be used for output voltage regulation. Examples of isolated power converters include, but are not limited to, an LLC (inductor-inductor-capacitor) resonant converter, isolated boost converter, dual active bridge (DAB) converter, LCLC converter, active clamp flyback converter, flyback converter, SEPIC converter, Zeta converter, and Cuk converter. According to embodiments, the output voltage value Vo may be transferred from secondary side to primary side with around, e.g., 50 μs to 200 μs delay when an analog optocoupler is used, or with, e.g., 1 μs to 5 μs delay when a digital isolator is used. The steady state output voltage value Vo_ss may be transferred from secondary side to primary side of the isolated power supply with same accuracy as, e.g., the ADC of an MCU located at the secondary side (e.g., MCU1 in FIG. 2 or 3). For example, if the ADC of an MCU at secondary side is 12 bits, the accuracy of Vo_ss at primary side will also be 12 bits. Thus, according to embodiments, substantially no accuracy loss is introduced during the transfer, and embodiments may achieve output voltage regulation with a high level of accuracy, e.g., Vo regulation to about 0.5% of a normal output voltage (e.g., a design value) or better.

Whereas embodiments are described herein based on transferring signals relating to voltage values across the isolation barrier of an isolated converter, they are not limited thereto. Signals relating to other parameters, such as current, power, status, temperature, etc. may also be transferred using the same coding techniques.

To maintain isolation, embodiments may be implemented with a controller on each side of the isolation barrier. Although not essential, the controller on the primary side may be the same as the controller on the secondary side. Each controller may be implemented with a programmable digital device which may be in the form of a VLSI integrated circuit (IC) suitable for embedded applications, such as, for example, a field-programmable gate array (FPGA), an application-specific integrated circuit (ASIC), a microcontroller unit (MCU), etc. Each controller may contain one or more processor (e.g., CPUs) capable of executing programmed instructions, memory, and programmable input/output peripherals such as analog to digital and digital to analog converters. The memory may include non-volatile memory used to store one or more program (i.e., computer code) that provide instructions or processing steps corresponding to algorithms, e.g., in some embodiments, one or more of Algorithms 1-4 set forth herein, for carrying out specific functions or tasks, and to store data. The memory may include one or more of random access memory (RAM) such as ferroelectric RAM, NOR flash, or programmable read-only memory (PROM) such as OTP ROM. For the purpose of this description MCUs are used as the controllers. Software products based on embodiments described herein, such as, for example, one or more of Algorithms 1-4, may be implemented in new hardware such as isolated converter circuits, or they may be used in to retrofit existing hardware by updating controller software according to one or more embodiments.

FIG. 4 shows a typical waveform of a logic pulse signal. Two parameters are needed to define a pulse waveform: Ton time and period, Ts. Here, Ton is defined as the time interval when the pulse signal at logic high level. That is, for any logic pulse signal, if Ton and Ts are defined, the logic pulse waveform is defined and is unique. In FIG. 4, the waveforms of two pulse signals are shown. They have the same Ton and same Ts. It is noted that the voltage value during Ton interval is not critical. It can be from about 3.3 V to about 5 V. Similarly, the voltage value during Ts-Ton interval is low but not critical, such as 0.1 V to about 0.5 V, or 0 V.

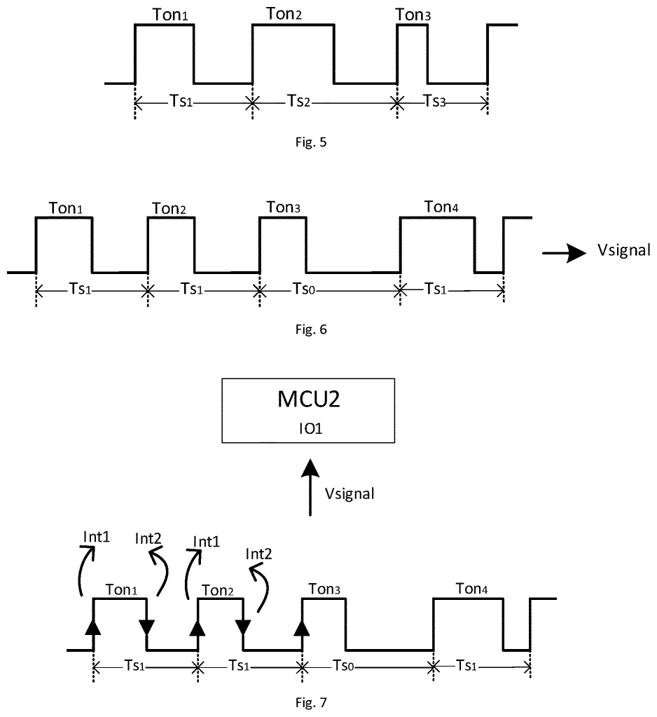

FIG. 5 shows the waveform of three pulse signals with different values of Ton and Ts. The first pulse is defined by Ton1 and Ts1; the second pulse is defined by Ton2 and Ts2; and third pulse is defined by Ton3 and Ts3. In particular:
The value of Ton may be changed significantly from one pulse signal to the next. For example, Ton2 and Ton3 are significantly different.
The value of Ts may be changed significantly from one pulse signal to the next. For example, Ts2 and Ts3 are significantly different.

As used herein, the term “pulse signal” refers to a pulse that occurs during one period.

According to embodiments described herein, for one pulse signal, its logic high time interval Ton is used to represent the value of the output voltage Vo, and its period Ts is used to represent a logic value, such as logic 1 or logic 0. Therefore, each pulse signal contains two pieces of information. One is analog information since Ton may be changed continuously. For example, Ton can be changed from zero (0 μs) to Ton_max (100 μs). The other (Ts) is digital information, such as logic 0 (zero) or logic 1 (one). Therefore, two switching periods, Ts0 and Ts1, are needed to represent logic 0 and logic 1. For the purpose of this description it is assumed that Ts0 represents logic 0 and Ts1 represents logic 1.

FIG. 6 shows a waveform of four pulse signals with four different Ton values and Ts1, Ts1, Ts0, Ts1. These four pulse signals may, for example, contain four output voltage values, which are represented by four Ton values and logic values of 1, 1, 0, 1 (as period Ts1 represents logic 1 and period Ts0 represents logic 0). The combination of these four pulse signals is defined as Vsignal for easier reference. It is noted that Ton values may also represent other analog values, such as output power, output current, etc.

FIG. 7 shows a method that may be used to retrieve the information contained in Vsignal. This method may be implemented by the primary side controller such as an MCU or similar programmable device, e.g., MCU2 in FIGS. 1, 2, and 3. For the purpose of this description, the primary side controller will be referred to as MCU2 and the secondary side controller will be referred to as MCU1. For example, Vsignal is connected to an Input/Output pin (IO pin) of the MCU2, 101. MCU2 executes an algorithm (i.e., computer code), an embodiment of which is shown in Algorithm 1, that causes the MCU to carry out processing steps to retrieve the information contained in the Vsignal.

Algorithm 1. Decoding information in the Vsignal on the primary side.

| | |
|---|---|
| Step 1 | At the rising edge of a first pulse signal, MCU2 will enter interrupt |
| Interrupt Routine 1, Int1 | routine 1, Int1. |
| Task 1.1 | Read the counter 1 value as COUNT_Ts_previous. This value is the |
| | period of the previous pulse which may be Ts0 or Ts1, or Tss which is |
| | the period of a starting pulse, as described below. |
| Task 1.2 | Reset counter 1 and restart counter 1. |
| Task 1.3 | Set the next interrupt trigger to falling edge trigger. |
| Task 1.4 | Exit interrupt routine 1. |
| Step 2 | At the falling edge after the Ton1, MCU2 will enter the interrupt routine |
| Interrupt Routine 2, Int2 | 2, Int2. |
| Task 2.1 | Read the counter 1 value, as COUNT_Ton1. This value, COUNT_Ton1, is |
| | the value of Ton1. |
| Task 2.2 | Set the next interrupt trigger to rising edge trigger. |
| Task 2.3 | Exit interrupt routine 2. |
| Step 3 | Repeat step 1 to step 2. |

The above algorithm may be repeated four times such that after four iterations, four Ton values and four period values may be obtained by MCU2 as following: COUNT_Ton1, COUNT_Ton2, COUNT_Ton3, COUNT_Ton4, and COUNT_Ts1, COUNT_Ts2, COUNT_Ts3, COUNT_Ts4. It is noted that COUNT_Tonj, j=1, 2, 3, 4, represents the Ton value of the pulse signals Ton1, Ton2, Ton3, and Ton4. So, the values of Ton1, Ton2, Ton3, and Ton4 are obtained by MCU2. By setting the time interval of Ton based on the output voltage Vo (as described below), then four output voltages at four different time instants, i.e., four instantaneous output voltages, are obtained at the primary side of MCU2.

COUNT_Tsj, j=1, 2, 3, 4, represents the period of the pulse signals. In the waveforms as shown in FIG. 7, they are Ts1, Ts1, Ts0, and Ts1. By definition, Ts1 represents logic 1 and Ts0 represents logic 0. Therefore, in this example a four bit digital value of 1101 is obtained by MCU2.

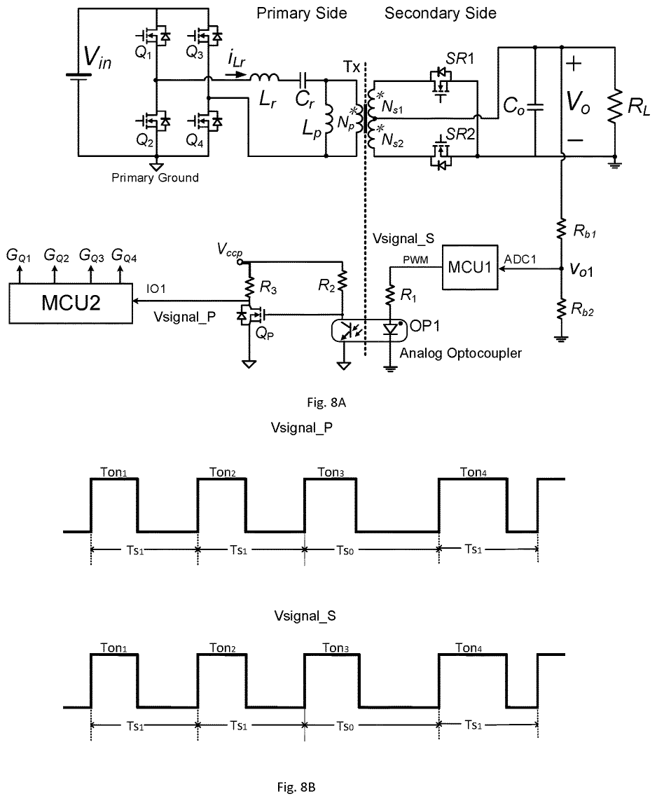

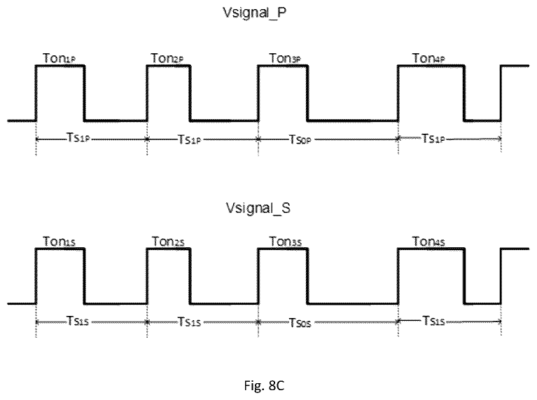

FIG. 8A is a schematic diagram of a circuit that may be used for transferring pulse signals from secondary side to primary side, according to some embodiments. A strategy for producing Vsignal at the secondary side, i.e., Vsignal_S, according to an embodiment based on sensing the output voltage Vo of the converter will now be described with reference to FIG. 8A. Referring to FIG. 8A, MCU1 is located at the secondary side. The output voltage of the power supply, Vo, is attenuated to Vo1 and the analog to digital converter input ADC1 of MCU1 senses the Vo1, or equivalently the Vo value. MCU1 executes an algorithm (i.e., computer code), an embodiment of which is shown in Algorithm 2, that causes the MCU1 to carry out processing steps to encode the information contained in the Vsignal. In this embodiment MCU1 is configured with a 12-bit ADC.

Algorithm 2. Encoding information in the Vsignal on the secondary side.

| | |
|---|---|
| Task 3.1 | Sample Vo1 at pre-determined time interval and convert it into digital value |
| | as Vo_digital using ADC1. Vo_digital is a 12-bit binary number stored in MCU1. |
| Task 3.2 | Convert the Vo_digital into a Ton value according to a pre-determined ratio. |
| | For example, for Vo = 30 V, Ton = 100 μs. |
| Task 3.3 | Calculate the average value of Vo over multiple samples, e.g., over 128 |
| | samples, as Vo_avg128. |
| Task 3.4 | Convert Vo_avg128 into a 12-bit digital value. |
| Task 3.5 | Use a pulse width modulation (PWM) function or a timer function to generate |
| | 12 PWM signals. |
| Task 3.6 | The Ton value of these 12 PWM signals are the sampled Vo value. The |
| | switching period of these 12 PWM signals are Ts1 or Ts0 which correspond to |
| | digital value of Vo_avg128. |

Vsignal_S may be transferred to the primary side by an analog optocoupler, which is less expensive and is usually slower than a digital isolator. MOSFET Qp is used to reduce the rise time and fall time of the pulse signal. An example of primary and secondary side waveforms Vsignal_P and Vsignal_S is shown in FIG. 8B for ideal conditions. At the primary side, the pulse signal Vsignal_P is obtained. Vsignal_P is connected to an input/output pin (101) of MCU2. MCU2 performs the task 1.1 to 1.4 and task 2.1 to 2.3 of Algorithm 1 as shown above to retrieve the values of Tonj (j=1 to 12) and Tsj (j=1 to 12). It is noted that a digital isolator or a digital optocoupler may also be used to transfer the pulse signal from secondary side to primary side. With a digital isolator (digital optocoupler), the pulse frequency may be increased since the delay time of the digital isolator (digital optocoupler) is smaller.

The examples provided below further illustrate certain features of embodiments, and are not intended to be limiting in any way.

### Example 1

The following assumptions are made to simplify the description in this example:
Assumption #1: The output voltage Vo=30 V and it does not change.
Assumption #2: When Vo=30 V, Ton value is 100 μs.
Assumption #3: ADC is 12-bit.

Therefore:

$$( 30 ) 10 = ( 0000 , 0001 , 1110 ) 2 \qquad ( 3 )$$

Here (30)10 means the value of 30 in decimal system. (0000,0001,1110) 2 means the value 30 in a 12-bit binary system. The comma (,) in the binary value expression is used for easier reading. Therefore (30)10=(0000,0001,1110)2=(000000011110)2.

Assumption #4: In assumption 3 above, the first 7 bits are zero and are not utilized. In order to use the full resolution of 12 bits, the value 30 V can be re-written as:

$$30 V = 30 , 000 mV = 3 , 000 \times 10 mV , and ( 3 , 000 ) 10 = ( 1011 , 1011 , 1000 ) 2 \qquad ( 4.1 )$$

$$30 V = ( 1011 , 1011 , 1000 ) 2 \times 10 mV \qquad ( 4.2 )$$

That is, 30 V can be expressed in binary system as (1011,1011,1000) 2 times 10 mV. In the description below, all voltages are expressed by 10 mV. For example, 30 V is expressed by 3,000×10 mV; 30.1 V is expressed as 3,010×10 mV; 29.5 V is expressed as 2,950×10 mV; etc. For example, in digital format with 12-bit,

$$30 V is expressed as : ( 3 , 000 ) 10 = ( 1011 , 1011 , 1000 ) 2 \qquad ( 5.1 )$$

$$30.1 V is expressed as : ( 3 , 010 ) 10 = ( 1011 , 1100 , 0010 ) 2 \qquad ( 5.2 )$$

$$29.5 V is expressed as : ( 2 , 950 ) 10 = ( 1011 , 1000 , 0110 ) 2 \qquad ( 5.3 )$$

$$10.05 V is expressed as : ( 1 , 050 ) 10 = ( 0100 , 0001 , 1010 ) 2 \qquad ( 5.4 )$$

Assumption #5: The pulse period corresponding to logic 1 is Ts1 and the pulse period corresponding to logic 0 is Ts0. Considering that Ton will be longer when Vo value is larger, in order to keep enough resolution for reliable operation, Ts0 and Ts1 values may be selected as, e.g., Ts0=160 μs, Ts1=150 μs.

In some embodiments Ts0, Ts1 should be longer than maximum possible Ton value, which depends on the output voltage. For example, assuming Ton=100 μs for Vo=30 V and maximum output voltage is 35 V, then Ton_max=116.7 μs.

Based on the above assumptions, and based on the processing tasks as outlined in the embodiment of Algorithm 2 from Task 3.1 to task 3.6, MCU1 will produce 12 PWM pulse signals as listed in Table 1.

TABLE 1
PWM pulse signals produced by MCU1 according to one embodiment.

| Pulse # | 1 | 2 | 3 | 4 | 5 | 6 | 7 | 8 | 9 | 10 | 11 | 12 |
|---|---|---|---|---|---|---|---|---|---|---|---|---|
| Ton (μs) | 100 | 100 | 100 | 100 | 100 | 100 | 100 | 100 | 100 | 100 | 100 | 100 |
| Ts (μs) | 150 | 160 | 150 | 150 | 150 | 160 | 150 | 150 | 150 | 160 | 160 | 160 |
| Logic # | 1 | 0 | 1 | 1 | 1 | 0 | 1 | 1 | 1 | 0 | 0 | 0 |

In the above table, the Ton time is always 100 μs since the output voltage does not change (Assumption #1). The average value of the output voltage, Vo_avg128, is also 30 V, which corresponds to binary value of (1011,1011,1000) 2.

Using the circuit diagram as shown in FIG. 8A, the above 12-bit pulse signal may be transferred from secondary side to primary side. MCU2 at primary side will measure the Ton value and to obtain the Vo information and measure the pulse period (Ts0 or Ts1), and convert the 12-bit binary signal into the average value of the output voltage.

The following are noted:
Note 3.1: Ton time may be updated at the rate of the Ts (Ts0 or Ts1), which is every 150 μs or 160 μs in this embodiment. Therefore, the value of the output voltage may be transferred from secondary side to primary side every Ts time interval (150 μs or 160 μs in this embodiment).
Note 3.2: It requires 12 periods to transfer the average value of Vo, such as Vo_avg128. In the above example, the total time interval for the 12 pulses is 7×150 μs+5×160 μs=1,850 μs=1.85 ms. That is, it will take longer time to transfer the average value of the output voltage. The average value will be updated around every 1.85 ms. Since the output voltage value could be different from 30 V (the steady state value), the actual total time interval for the 12 pulses is different. However, the longest time interval will occur when all the logic bits are zero, i.e., at 0 V. The longest time interval is 12×160 μs=1,920 μs=1.92 ms.
Note 3.3: Due to time delay in the optocoupler circuit and other errors, the Ton value measured at primary side may be slightly different from the Ton value generated by the secondary side MCU1.
Note 3.4: The Vo_avg may be transferred from secondary side to primary side without any loss of accuracy, since it is transferred in digital format. That is, if a 12-bit ADC is used at secondary side MCU1, the value obtained at primary side MCU2 will also have the accuracy of 12 bits.
Note 3.5: The pulse period applied to 101 of MCU2 will be slightly different from the pulse period as generated by the secondary side MCU1. The algorithm in MCU2 may be configured to identify this small variation. The waveforms of FIG. 8C show a slight difference in timing between the secondary side signal and primary side signal (note labelling of different primary and secondary Ton, Ts1, and Ts0). Such waveforms may be obtained using, for example, the circuit of FIG. 8A.

### Example 2

In a practical implementation, a starter pulse frame may be used to indicate the start of the 12-bit data stream. One or more pulses with Ton value and Tss period value may be used as the starter pulse frame. For example, Tss=140 μs may be selected for period of the starter pulse frame, and two or more pulses may be used as the starter frame. Table 2 shows the pulse signals when two starter pulses are used. The starter pulses may be the same length, as shown in Table 2, or they may be of different lengths.

TABLE 2
Starter pulse frame and information frame with PWM pulse
signals produced by MCU1 according to one embodiment.

| Pulse # | 1 | 2 | 3 | 4 | 5 | 6 | 7 | 8 | 9 | 10 | 11 | 12 | 13 | 14 |
|---|---|---|---|---|---|---|---|---|---|---|---|---|---|---|
| Ton (μs) | 100 | 100 | 100 | 100 | 100 | 100 | 100 | 100 | 100 | 100 | 100 | 100 | 100 | 100 |
| Ts (μs) | 140 | 140 | 150 | 160 | 150 | 150 | 150 | 160 | 150 | 150 | 150 | 160 | 160 | 160 |
| Logic # | ss | ss | 1 | 0 | 1 | 1 | 1 | 0 | 1 | 1 | 1 | 0 | 0 | 0 |

In the above table, the first two pulses are starter frame with 140 μs period. The on time of the starter pulses also contains the output voltage information, but the period is significantly different from Ts0 (160 μs) and Ts1 (150 μs). When the primary side MCU2 measures Tss value for the pulse period, it knows that the following bits are useful data.

The secondary side MCU1 will generate the above 14 pulses as one set of data. This pulse signal Vsignal_S is transferred to primary side to produce Vsignal_P. The primary side MCU2 will read the information contained after the starter pulses.

Other information from secondary side may also be added into the information frame after the 12-bit Vo_avg information. For example, an additional four or more bits may be added for output current information. In some embodiments a supplemental frame including an additional 4 bits, or other number of bits, may be added after the information frame, so that 16 different conditions may be transferred from secondary side to primary side. For example, for power delivery (PD) applications, a sleep signal may be transferred from secondary side to primary side. Other information, such as an indication that a condition of output voltage/power is good, etc., may also be transferred to primary side using one or more of the four bits of the supplemental frame. Thus, in some embodiments useful information may be contained in 12 bit+4 bit=16 bit binary code (e.g., 12 bits for output voltage and 4 bits for information bits). Such an embodiment is shown in Table 3.

In order to ensure that the data is not corrupted, cyclic redundancy check (CRC) bits may be appended after the data, as a check frame. For example, four CRC bits may be added at the end of the 16 bit data or after the supplemental frame. In such embodiments the total useful bit number transferred from secondary side to primary side may be 12+4+4=20 bit. The following table shows an example of the data structure:

TABLE 3
Data structure with starter frame, information frame, supplemental
frame, and check frame, according to one embodiment.

| Pulse # | 1 | 2 | 3 | 4 | 5 | 6 | 7 | 8 | 9 | 10 | 11 | 12 |
|---|---|---|---|---|---|---|---|---|---|---|---|---|
| Status | Starter Frame | | Information Frame (e.g., Vo_avg value) | | | | | | | | | |
| Ton (μs) | Ton | Ton | Ton | Ton | Ton | Ton | Ton | Ton | Ton | Ton | Ton | Ton |

| Pulse # | 13 | 14 | 15 | 16 | 17 | 18 | 19 | 20 | 21 | 22 |
|---|---|---|---|---|---|---|---|---|---|---|
| Status | Information Frame | | Supplemental Frame | | | | Check Frame | | | |
| | (e.g., Vo_avg value) | | (e.g., information bits) | | | | (e.g., CRC bits) | | | |
| Ton (μs) | Ton | Ton | Ton | Ton | Ton | Ton | Ton | Ton | Ton | Ton |

The secondary side MCU1 will generate CRC bits based on the 12 bit Vo_avg value and information bit value. Therefore, the data set includes 22 pulses. The period of the first two pulses is Tss (140 μs) in the above example. The period of the next 20 pulses is either Ts0 or Ts1, 160 μs or 150 μs in the above example. The Ton time of every pulse represents the latest sampled value of the output voltage. Therefore, the latest output value is transferred to primary side in every pulse, or for every 140 μs, or 150 μs, or 160 μs. The average output voltage Vo_avg and digital information is transferred from secondary side to primary side at a time interval between 140×2+150×20=3,280 μs=3.28 ms, and 140×2+160×20=4,480 μs=3.48 ms. That is, the average output voltage value and digital information will be transferred from secondary side to primary side approximately every 3.5 ms.

In the above example, Ton=100 μs for 30 V output voltage is used. Ts1=150 μs, Ts0=160 μs, and Tss=140 μs are used. Based on particular implementations, system requirements, whether digital isolator or analog optocoupler is used, as well as other factors such as the performance of the MCU1, MCU2, other values of Ton, Ts0, Ts1, and Tss may be used. In some embodiments, the information frame may contain information about other analog parameters at the secondary side, such as the output current, output power, etc. In some embodiments, the information frame may include 24 bits, where the first 12 bits contain the average output voltage value, and the second 12 bits contain the average output current value. In some embodiments, the number of information bits in the supplemental frame may be greater than four bits. In various embodiments, the number of bits in one or more of the starter frame, information frame, supplemental frame, and check frame may be different from the numbers of bits shown in the embodiment of Table 3 according to the type of information being encoded, and whether the information is analog information or digital information. In some embodiments, the Ton time of all pulses in all the frames may be the same. In some embodiments, the Ton time of pulses in one or more frame may be different within the one or more frame, and/or may be different between the one or more frames. In some embodiments, the Ton time of each pulse in all the frames is different, for example, in embodiments where Ton represents the instantaneous output voltage, the Ton time may be continuously changed according to the instantaneous output voltage. In some embodiments, the pulse width of different pulses may be encoded according to different parameters, for example, parameters such as output voltage, output current, and output power. For example, hen the instantaneous values of two analog parameters are transferred from secondary side to primary side, the pulse width of the first pulse may be used to represent instantaneous output voltage, the pulse width of the second pulse may be used to represent the instantaneous current, the pulse width of the third pulse may used to represent the instantaneous of output voltage, and so on.

Summary of features that may be implemented in various combinations according to embodiments:
A Ton value of a pulse signal is used to represent an analog value and a period of the same pulse signal is used to represent binary value. One period, Ts0, represents digital 0, and another period, Ts1, represents digital 1.
Both the analog and digital information is transferred from secondary side to primary side using a set of pulse signals including: (1) starter frame; (2) information frame including digital bits representing the accurate average output voltage together with analog information representing the instantaneous output voltage; (3) supplemental frame including digital bits representing other digital information; and (4) check frame including CRC bits.
An analog signal, such as a sampled output voltage Vo, is transferred to primary side in every pulse, such as every 150 μs. The average output voltage and other digital information is transferred to primary side in every information frame, e.g., about every 3.5 ms.
The average value of the output voltage may be transferred to primary side without any accuracy loss.
The value of Ton will have a small error as compared with the actual Vo value due to the time delay in the circuit, as well as the clock frequency tolerance of MCU1 and MCU2.

### Calibration of Ton

Calibration can be used to correct the error in Ton. The following algorithm may be implemented in the primary side MCU2 and secondary side MCU1, and provides a method to calibrate the Ton based on an accurate determination of the average output voltage.

Algorithm 3. Calibration procedure according to one embodiment.

| Step #4.1 | MCU1 calculates the average value of the measured output voltage Vo over a | |
|---|---|---|
| | long period of time, such as, e.g., 500 ms to obtain the steady state average | |
| | value of the output voltage, Vo_avg_ss. | |
| Step 4.2 | MCU1 transfers the Vo_avg_ss to primary side MCU2. | |
| Step 4.3 | MCU2 at primary side calculates the average value of Ton over a long period of | |
| | time (e.g., similar to the secondary side calculation, such as around 500 ms). | |
| | The average steady state value of Ton is calculated as Ton_avg_ss. | |
| Step 4.4 | Assume the theoretical relationship between Ton and Vo is: | |
| | Vo = K * Ton | (6) |
| | where Ton is measured at each pulse signal. K is a design parameter. (E.g., in | |
| | one embodiment, when Vo = 30 V, Ton = 100 μs, K = 30 V/100 μs = 0.3 V/μs.) | |
| Step 4.5 | MCU2 calculates the relationship between the actual Vo value and measured | |
| | Ton value as: | |
| | K_actual = Vo_avg_ss/Ton_avg_ss | (7) |
| Step 4.6 | MCU2 calculates the accurate output voltage as: | |
| | Vo_actual = K_actual * Ton | (8) |

The Ton value may be generated by a timer in the secondary side MCU1. The system clock frequency of MCU1 may have a tolerance of around 1% to 10%, depending on the model and make of the MCU. It is assumed that the nominal clock frequency of MCU1 is F_clock1=10 MHz, or T_clock1=100 ns. Then, a counter value of COUNT1=1,000 will generate a pulse width of Ton=100 μs. That is, a count value of COUNT1=1,000 corresponds to 100 μs. In the above example, if the ADC1 sensed value is equivalent to Vo=30 V, MCU1 will generate a count value of COUNT1=1,000. Under this condition, Vo_avg_ss=30 V and Ton_avg_ss=100 μs. Therefore, MCU2 calculates equation (8) as:

$$K\_actual = Vo\_avg \_ss / Ton\_avg \_ss = 30 V / 100 μ s = 0.3 V / μ s \qquad ( 9 )$$

### Example 3

This example illustrates how the calibration procedure embodiment of Algorithm 3 works. In this example it is assumed that due to temperature variation, the system clock frequency is increased by 5%:

$$F\_clock1 \_new = 10 * 1.05 = 10.5 MHz , and T\_clock1 \_new = 1 / 10.5 MHz = 95.2 ns \qquad ( 10 )$$

Since the code of MCU1 cannot detect the clock frequency change, for an output voltage value of 30 V, it will still generate COUNT1=1,000. With the new clock frequency, the actual

$$Ton\_new = 1 , 000 \times 95.2 ns = 95.2 μ s .$$

Without the calibration, the primary side MCU2 will “interpret” the output voltage as:

$$Vo\_new = 0.3 * 95.2 = 28.56 V$$

This error cannot be corrected by itself. With the calibration method described above, the actual K value is calculated as following:

$$Vo\_avg \_ss = 30 V ( transferred by digital method , with long time delay ) \qquad ( 11.1 )$$

$$Ton\_avg \_ss = 95.2 μs ( calculated based on the actual measurement ) \qquad ( 11.2 )$$

$$K\_actual = Vo\_avg \_ss / Ton\_avg \_ss = 30 V / 95.2 μ s = 0.31513 V / μ s \qquad ( 11.3 )$$

Then the actual output voltage can be calculated using equation (8) as:

$$Vo\_actual = K\_actual * Ton\_new = 0.31513 * 95.2 = 30. V \qquad ( 11.4 )$$

It will be apparent that a calibration method based on embodiments described herein may also be used to correct the error introduced by the time delay shift of the optocoupler. An advantage of the calibration method is that the accurate output voltage is transferred across the isolation barrier in a digital format, which does not lose accuracy during the transition. An average value over a large number of samples of Vo, such as 10,000 samples, may be used to ensure that the converter circuit is operating at steady state condition. Since the clock frequency of MCU1 will not change significantly over a short period of time, the calibration may be performed at, e.g., around 100 ms to 10 second interval.

### Calibration of Ts1 and Ts0

Since the actual pulse period (Ts0 and Ts1) is measured at primary side MCU2, if the clock frequency of secondary side MCU1 changes, the pulse period, Ts0 and Ts1, will also change. Therefore, it may also be required that Ts0 and Ts1 be calibrated.

With reference to Table 3, three pulse periods are used: starter period Tss, logic 1 period Ts1 and logic 0 period Ts0. The relationship between Tss, Ts1, and Ts0 are design parameters and are known. In the above example, Tss=140 μs, Ts1=150 μs, and Ts0=160 μs. The position of the starter pulse is known and therefore it can be identified in the implementation. The period of starter pulse is the smallest. Therefore, the length of Tss can be used as a reference to calibrate the length of Ts1 and Ts0. Under normal operation conditions:

$$K\_Ts1 = Ts 1 / Tss = 150 μ s / 140 μ s = 1.07143 \qquad ( 12.1 )$$

$$K\_Ts0 = Ts 0 / Tss = 160 μ s / 140 μ s = 1.14286 \qquad ( 12.2 )$$

If the clock frequency of MCU1 changes from, e.g., 10 MHz to 10.5 MHz, Tss will change from Tss=140 μs to Tss_new=133.28 μs. The new Tss value Tss_new can be used to calibrate Ts1 and Ts0 as following:

$$Ts1\_new = Tss\_new * K\_Ts1 = 133.28 * 1.07143 = 142.8 μs \qquad ( 13.1 )$$

$$Ts0\_new = Tss\_new * K\_Ts0 = 133.28 * 1.14286 = 152.32 μ s \qquad ( 13.2 )$$

Therefore, the calibration of Ts1 and Ts0 may be done using with the following steps:

Algorithm 4. Calibration of Ts1 and Ts0 according to one embodiment.

| Step 5.1 | The primary side MCU2 take the measured the period of starter pulse, Tss. | |
|---|---|---|
| Step 5.2A | If the measured Tss_new is close to the design value (e.g., such as Tss_new is | |
| | within +/− 1 μs of 140 μs), the design value for Ts1 and Ts0 may be used. Go to | |
| | Step 5.3. | |
| Step 5.2B | If the measured Tss_new is different from the design value (e.g., such as | |
| | the difference between measured Tss_new and 140 μs is larger than 1 μs), then new | |
| | Ts1 and Ts0 are calculated as follows. | |
| | Ts1_new = K_Ts1 * Tss_new | (14.1) |
| | Ts0_new = K_Ts0 * Tss_new | (14.2) |

| | |
|---|---|
| | Wherein K_Ts1 and K_Ts0 are defined in equations (12.1) and (12.2). |
| Step 5.3 | After a delay (e.g., around 100 ms to 10 s), go to Step 5.1. |

In a practical implementation, a hysteresis T_hys will be introduced to detect Ts1 and Ts0. For example, if measured period is between Tss−T_hys and Tss+T_hys, the starter pulse is detected. A measured pulse period between Ts1−T_hys and Ts1+T_hys will be interpreted as logic 1. A measured pulse period of Ts0−T_hys and Ts0+T_hys will be interpreted as logic 0.

Since in MCU2, a counter value is used to represent the time interval, such as Ton and Ts, the above calibration method also calibrates the clock frequency tolerance of MCU2. The details are similar to the above description and are not provided here.

### EQUIVALENTS

It will be appreciated that modifications may be made to the embodiments described herein without departing from the scope of the invention. Accordingly, the invention should not be limited by the specific embodiments set forth but should be given the broadest interpretation consistent with the teachings of the description as a whole.

1. A method for transferring a signal across an isolation barrier, comprising:
encoding the signal according to at least first and second parameters at a second side of the isolation barrier;
using one or more isolating device to transfer the signal to a first side of the isolation barrier;
decoding the signal to recover the at least first and second parameters on the first side of the isolation barrier;
wherein encoding the signal comprises encoding a first feature of the signal according to the first parameter and encoding a second feature of the signal according to the second parameter.

2. The method of claim 1, comprising organizing the signal in an information transfer protocol, comprising:
a starter frame having a first selected number of pulses; and
an information frame having a second selected number of pulses comprising the first feature and the second feature;
wherein encoding comprises encoding the first feature of the second selected number of pulses according to analog information about the first parameter and encoding the second feature of the second selected number of pulses according to digital information about the second parameter.

3. The method of claim 2, wherein the first feature of at least one of the first and second selected number of pulses is a pulse width and the second feature of the second selected number of pulses is a pulse period.

4. The method of claim 3, wherein encoding comprises encoding analog information about the first parameter in at least one of the first and second selected number of pulses by adjusting the pulse width according to the analog information.

5. The method of claim 3, wherein encoding comprises encoding digital information about the second parameter in the second selected number of pulses by selecting a first pulse period to be digital 1 (Ts1) and selecting a second pulse period (Ts0) to be digital 0.

6. The method of claim 2, comprising encoding the signal with a supplemental frame having a selected number of pulses that encode information about one or more other parameters of the second side of the isolation barrier.

7. The method of claim 6, wherein encoding comprises encoding analog information about the one or more other parameters in the selected number of pulses by adjusting the pulse width according to the one or more other parameters.

8. The method of claim 2, comprising encoding the signal with a check frame having a selected number of pulses that encode cyclic redundancy check (CRC) bits.

9. The method of claim 8, wherein encoding comprises encoding analog information about one or more other parameters in the selected number of pulses by adjusting the pulse width according to the one or more other parameters.

10. The method of claim 5, comprising using a length of a pulse in the starter frame as a reference to calibrate a length of Ts1 and Ts0 at the first side of the isolation barrier.

11. The method of claim 5 comprising using a digital value of the second parameter transferred from the second side of the isolation barrier to calibrate an actual value of the first parameter at the first side of the isolation barrier.

12. The method of claim 1, comprising using a second controller at the second side of the isolation barrier to implement encoding the signal, and using a first controller at the first side of the isolation barrier to implement decoding the signal.

13. The method of claim 12, wherein the isolation barrier isolates first (primary) and second (secondary) sides of an isolated power converter.

14. The method of claim 1, wherein the isolating device comprises a device selected from an optocoupler and a digital isolator.

15. The method of claim 1, wherein the one or more isolating device comprises an optocoupler.

16. The method of claim 13, wherein the first parameter is instantaneous output voltage of the isolated power converter and the second parameter is average output voltage of the isolated power converter.

17. The method of claim 12, wherein the first controller uses information about the first parameter and/or information about the second parameter obtained from decoding the signal to control operation of a circuit on the first side of the isolation barrier.

18. Programmed media for use with at least a first controller and a second controller connected to respective first and second sides of one or more isolating device disposed across an isolation barrier, comprising:
a code stored on non-transitory computer readable storage media compatible with processors of the at least first and second controllers, the code containing instructions to direct the processors to implement a strategy to transfer a signal across the isolation barrier, comprising:
the second controller encoding a signal according to at least first and second parameters at the second side of the isolation barrier and outputting the encoded signal to the one or more isolation device;
the first controller receiving the encoded signal from the one or more isolation device and decoding the signal to recover the at least first and second parameters on the first side of the isolation barrier;
wherein encoding the signal comprises encoding a first feature of the signal according to the first parameter and encoding a second feature of the signal according to the second parameter.

19. The programmed media of claim 18, wherein the second controller organizes the signal in an information transfer protocol, comprising:
a starter frame having a first selected number of pulses; and
an information frame having a second selected number of pulses comprising the first feature and the second feature;
wherein encoding comprises encoding the first feature of the second selected number of pulses according to analog information about the first parameter and encoding the second feature of the second selected number of pulses according to digital information about the second parameter.

20. The programmed media of claim 19, wherein the first feature of at least one of the first and second selected number of pulses is a pulse width and the second feature of the second selected number of pulses is a pulse period.

21. The programmed media of claim 19, wherein encoding comprises encoding analog information about the first parameter in at least one of the first and second selected number of pulses by adjusting the pulse width according to the analog information.

22. The programmed media of claim 19, wherein encoding comprises encoding digital information about the second parameter in the second selected number of pulses by selecting a first pulse period to be digital 1 (Ts1) and selecting a second pulse period (Ts0) to be digital 0.

23. The programmed media of claim 19, comprising encoding the signal with a supplemental frame having a selected number of pulses that encode information about one or more other parameters of the second side of the isolation barrier.

24. The programmed media of claim 23, wherein encoding comprises encoding analog information about the one or more other parameters in the selected number of pulses by adjusting the pulse width according to the one or more other parameters.

25. The programmed media of claim 19, comprising encoding the signal with a check frame having a selected number of pulses that encode cyclic redundancy check (CRC) bits.

26. The programmed media of claim 25, wherein encoding comprises encoding analog information about one or more other parameters in the selected number of pulses by adjusting the pulse width according to the one or more other parameters.

27. The programmed media of claim 22, comprising using a length of a pulse in the starter frame as a reference to calibrate a length of Ts1 and Ts0 at the first side of the isolation barrier.

28. The programmed media of claim 22 comprising using a digital value of the second parameter transferred from the second side of the isolation barrier to calibrate an actual value of the first parameter at the first side of the isolation barrier.

29. The programmed media of claim 22, wherein the first controller and the second controller are implemented in first (primary) and second (secondary) sides of an isolated power converter.

30. The programmed media of claim 29, wherein the first parameter is instantaneous output voltage of the isolated power converter and the second parameter is average output voltage of the isolated power converter.

31. The programmed media of claim 18, wherein the first controller uses information about the first parameter and/or information about the second parameter obtained from decoding the signal to control operation of a circuit on the first side of the isolation barrier.

32. An isolated power converter comprising:
a primary side controller;
a secondary side controller; and
one or more isolating device that transfers a pulse signal across an isolation barrier;
wherein the secondary side controller encodes information about at least one parameter of the isolated power converter by controlling at least one feature of the pulse signal according to levels of the at least one parameter.

33. The isolated power converter of claim 32, wherein:
the at least one feature is a period of the pulse signal; and
the secondary side controller encodes the information using at least two different periods of the pulse signal.

34. The isolated power converter of claim 32, wherein:
the at least one feature is a pulse duration of the pulse signal; and
the secondary side controller encodes the information using a variable pulse duration of the pulse signal.

35. The isolated power converter of claim 32, wherein:
a first feature is a period of the pulse signal;
a second feature is a pulse duration of the pulse signal; and
the secondary side controller encodes the information using at least two different periods and a variable pulse duration of the pulse signal.

36. The isolated power converter of claim 32, comprising the programmed media of claim 18.

37. The isolated power converter of claim 32, having a voltage regulation to about 0.5% or better of a normal output voltage.
